(19) United States
(12) Patent Application Publication
(10) Pub. No.: US 2021/0206652 A1
(43) Pub. Date: Jul. 8, 2021

(54) ANISOTROPIC MATERIALS AND METHODS OF FORMING ANISOTROPIC MATERIALS EXHIBITING HIGH OPTICAL ANISOTROPY

(71) Applicants: University of Southern California, Los Angeles, CA (US); Wisconsin Alumni Research Foundation, Madison, WI (US)

(72) Inventors: Shanyuan Niu, Los Angeles, CA (US); Graham Joe, Cambridge, MA (US); Mikhail A. Kats, Madison, WI (US); Jayakanth Ravichandran, Los Angeles, CA (US)

(21) Appl. No.: 17/058,645

(22) PCT Filed: May 24, 2019
(86) PCT No.: PCT/US2019/034067

§ 371 Date: Nov. 24, 2020

Related U.S. Application Data
(60) Provisional application No. 62/676,664, filed on May 25, 2018.

(51) Int. Cl. C01G 31/00; C01F 7/00; C01G 15/00; C01G 23/00; C01F 11/00; C01B 33/00; C01G 17/00

(52) U.S. Cl. CPC C01G 31/006; C01F 7/002; C01G 15/006; C01G 23/002; C01F 11/00; C01P 2004/04; C01G 17/006; C01P 2006/40; C01P 2002/72; C01P 2004/03; C01P 2002/85; C01B 33/00

(57) ABSTRACT

A method for forming a crystalline material having an anisotropic, quasi-one-dimensional crystal structure is disclosed. In various embodiments, the method includes: mixing a plurality of precursor materials together to form a combined precursor material, the plurality of precursor materials including a transition-metal ion or a main group ion and at least one of an alkaline earth ion or an alkali metal ion; and reacting the combined precursor material to obtain the crystalline material, the crystalline material having a formula ABX3, wherein A is the at least one of the alkaline earth ion or the alkali metal ion and B is the transition-metal ion surrounded by six anions (X), and wherein the quasi-one-dimensional anisotropic crystal provides a birefringence of at least 0.03, defined as the absolute difference in the real part of the complex-refractive-index values along different crystal axes, in at least a portion of one or N both of the visible-wave spectrum or the infrared spectrum.

### CROSS-REFERENCE TO RELATED APPLICATIONS

This application claims priority to, and the benefit of, U.S. Prov. Pat. Appl. Ser. No. 62/676,664, entitled “Optical Anisotropy,” filed on May 25, 2018, the entirety of which is incorporated herein for all purposes by this reference.

### STATEMENT AS TO FEDERALLY SPONSORED RESEARCH

This invention was made with government support under contract number FA9550-16-1-0335 awarded by the Air Force Office of Scientific Research (AFOSR), and contract number N00014-16-1-2556 awarded by the Office of Naval Research (ONR). The government has certain rights in this invention.

### FIELD

The present disclosure relates generally to optical anisotropy and, more particularly, to materials exhibiting large optical anisotropy and methods of making the same.

### BACKGROUND

Optical anisotropy is a fundamental building block for linear and non-linear optical components, such as, for example, polarizers, wave plates and phase-matching elements. In solid homogeneous materials, the strongest optical anisotropy is found in crystals such as, for example, calcite and rutile. Attempts to enhance anisotropic light-matter interaction often rely on artificial anisotropic microstructures or nanostructures that exhibit form birefringence. In this disclosure, rationally designed, giant optical anisotropy in single crystals of barium titanium sulphide (BaTiS₃) is demonstrated. This material shows an unprecedented, broadband birefringence (Δn) of up to 0.76 in the mid- to long-wave infrared, as well as a large dichroism window with absorption edges at 1.6 μm and 4.5 μm for light with polarization along two crystallographic axes on an easily accessible cleavage plane. The unusually large anisotropy is a result of the quasi-one-dimensional (quasi-1D) structure, combined with rational selection of the constituent ions to maximize the polarizability difference along different axes.

### SUMMARY

A method for forming a crystalline material having an anisotropic, quasi-one-dimensional crystal structure is disclosed in various embodiments, the method includes the steps of: mixing a plurality of precursor materials together to form a combined precursor material, the plurality of precursor materials including a transition-metal ion or a main group ion and at least one of an alkaline earth ion or an alkali metal ion; and reacting the combined precursor material to obtain the quasi-one-dimensional anisotropic crystal having a formula ABX₃, where A is the at least one of the alkaline earth ion or the alkali metal ion and B is the transition-metal ion or the main group ion surrounded by six anions (X), and where the quasi-one-dimensional anisotropic crystal provides a birefringence of at least 0.03, defined as the absolute difference in the real part of the refractive-index along different crystal axes, in at least a portion of one or both of the visible-wave spectrum or the infrared-wave spectrum. In various embodiments, the at least one of the alkaline earth ion or the alkali metal ion includes at least one of barium, strontium or calcium; and the transition-metal ion includes at least one of titanium, vanadium, or a main group element including at least one of aluminum, silicon, germanium or gallium.

In various embodiments, reacting the combined precursor material includes heating the combined precursor material to a predetermined temperature for a predetermined amount of time. In various embodiments, the predetermined temperature is at least 1472 degrees Fahrenheit (800 degrees C.) and the predetermined amount of time is at least 40 hours. In various embodiments, reacting the combined precursor material further includes heating the combined precursor material in an airtight vessel.

In various embodiments, the plurality of precursor materials further includes at least one of sulphur, selenium, iodine, chlorine, bromine or a related precursor material. In various embodiments, the crystalline material includes at least one of BaTiS₃, SrTiS₃, CsTaS₃, CsVS₃, CsNbS₃, RbTaS₃, RbVS₃, RbNbS₃, CsTaSe₃, CsVSe₃, CsNbSe₃, RbTaSe₃, RbVSe₃ or RbNbSe₃. In various embodiments, the crystalline material includes at least one of BaTiS₃, SrIiS₃, CaTiS₃, BaVS₃, SrVS₃, CaNTS₃, LaGaS₃, BaGeS₃, SrGeS₃, CaGeS₃, CaSiS₃, SrSiS₃, BaSiS₃, CeGaS₃ or EuGaS₃. In various embodiments, the crystalline material comprises BaTiS₃.In various embodiments, the crystalline material includes at least one of KNiCl₃, RbMgCl₃, RbCoCl₃, RbNiCl₃, RbCuCl₃, RbZnCl₃, RbMgBr₃, RbCoBr₃, RbNiBr₃, RbCuBr₃, RbZnBr₃, CsMgCl₃, CsCoCl₃, CsNiCl₃, CsCuCl₃, CsZnCl₃, CsMgBr₃, CsCoBr₃, CsNiBr₃, CsCuBr₃, CsZnBr₃, CsMgI₃, CsCoI₃, CsNiI₃, CsCuI₃ or CsZnI₃. In various embodiments, the crystalline material includes at least one of BaTiSe₃, SrTiSe₃, CaTiSe₃, BaVSe₃, SrVSe₃, CaVSe₃, LaGaSe₃, BaGeSe₃, SrGeSe₃, CaGeSe₃, CaSiSe₃, SrSiSe₃, BaSiSe₃, CeGaSe₃ or EuGaSe₃.

In various embodiments, the crystalline material includes atoms arranged in a parallel chain-like structure. In various embodiments, the crystalline material provides birefringence greater than 0.15 in at least a portion of one or both of the visible-wave spectrum or the infrared-wave spectrum. In various embodiments, the crystalline material provides birefringence greater than 0.3 in at least a portion of one or both of the visible-wave spectrum or the infrared-wave spectrum.

A method for forming a crystal exhibiting birefringence is disclosed. In various embodiments, the method includes the steps of: mixing a plurality of precursor materials together to form a combined precursor material, the plurality of precursor materials including a transition-metal ion and at least one of an alkaline earth ion or an alkali metal ion; and reacting the combined precursor material to obtain the crystal, having a formula ABX₃, where A is the at least one of the alkaline earth ion or the alkali metal ion and B is the transition-metal ion surrounded by six anions (X), and where the crystal provides birefringence of at least 0.03 in at least a portion of one or both of the visible-wave spectrum or the infrared-wave spectrum.

In various embodiments, the crystal provides an absolute linear dichroism of at least 0.2 at some wavelength within the visible-wave spectrum or the infrared-wave spectrum, defined as the difference in the imaginary part of the refractive index, k, for polarization along at least two crystallographic axes on a cleavage plane. The method of claim 15, wherein the crystal provides a difference in a wavelength within the visible-wave spectrum or the infrared-wave spectrum at which the imaginary part of the refractive index, k, reaches a value of 0.05 for light polarized parallel and perpendicular to the crystal c-axis. In various embodiments, at least one of the alkaline earth ion or the alkali metal ion includes at least one of barium, strontium or calcium; and the transition-metal ion includes at least one of titanium, vanadium, aluminum, silicon, germanium or gallium.

In various embodiments, reacting the combined precursor material includes heating the combined precursor material to a predetermined temperature for a predetermined amount of time and wherein the predetermined temperature is at least 1472 degrees Fahrenheit (800 degrees C.) and the predetermined amount of time is at least 40 hours. In various embodiments, the plurality of precursor materials further includes at least one of sulphur, selenium, iodine or chlorine.

In various embodiments, the crystal includes at least one of BaTiS₃, SrTiS₃, CaTiS₃, BaVS₃, SrVS₃, CaVS₃, LaGaS₃, BaGeS₃, SrGeS₃, CaGeS₃, CaSiS₃, SrSiS₃, BaSiS₃, CeGaS₃ or EuGaS₃. In various embodiments, the crystal comprises BaTiS₃. In various embodiments, the crystal includes at least one of BaTiSe₃, SrTiSe₃, CaTiSe₃, BaVSe₃, SrVSe₃, CaVSe₃, LaGaSe₃, BaGeSe₃, SrGeSe₃, CaGeSe₃, CaSiSe₃, SrSiSe₃, BaSiSe₃, CeGaSe₃ or EuGaSe₃.

In various embodiments, the crystal includes atoms arranged in a parallel chain-like structure. In various embodiments, the crystal provides the birefringence greater than 0.15 in at least a portion of one or both of the visible-wave spectrum or the infrared-wave spectrum. In various embodiments, the crystal provides the birefringence greater than 0.30 in at least a portion of one or both of the visible-wave spectrum or the infrared-wave spectrum.

### BRIEF DESCRIPTION OF THE DRAWINGS

The subject matter of the present disclosure is particularly pointed out and distinctly claimed in the concluding portion of the specification. A more complete understanding of the present disclosure, however, may best be obtained by referring to the following detailed description and claims in connection with the following drawings. While the drawings illustrate various embodiments employing the principles described herein, the drawings do not limit the scope of the claims.

FIG. 1A is a perspective view of a BaTiS₃ crystal plate, in accordance with various embodiments;

FIG. 1B is an axial view of the BaTiSi₃ crystal plate illustrated in FIG. 1A, viewed along the a-axis and showing TiSi₆ chains parallel to the c-axis, in accordance with various embodiments;

FIG. 1C is an axial view of the BaTiSi₃ crystal plate illustrated in FIG. 1A, viewed along the c-axis and showing hexagonal symmetry, in accordance with various embodiments;

FIG. 1D is a graph illustrating electronic polarizabilities of select candidate ions for a quasi-1D structure plotted as a function of atomic number, in accordance with various embodiments;

FIG. 1E is a graph illustrating absorption-coefficient spectra parallel and perpendicular to the c-axis, in accordance with various embodiments;

FIG. 2A is an optical image of a representative as-grown BaTiSi₃ crystal needle and crystal plate, in accordance with various embodiments;

FIG. 2B is a SEM image of a BaTiSi₃ crystal plate, in accordance with various embodiments;

FIG. 2C is an out-of-plane X-ray diffraction scan of a BaTiSi₃ crystal plate, in accordance with various embodiments;

FIG. 2D is a EDS mapping of barium atoms, titanium atoms and sulfur atoms on a BaTiS₃ crystal needle, in accordance with various embodiments;

FIG. 2E is a high-angle annular dark-field STEM image of BaTiSi₃ viewed along the a-axis, the inset representing the corresponding schematic crystal structure overlaid with the STEM image, in accordance with various embodiments;

FIG. 2F is a high-angle annular dark-field STEM image of BaTiSi₃ viewed along the c-axis, the inset representing the corresponding schematic crystal structure overlaid with the STEM image, in accordance with various embodiments;

FIG. 3A is a graph showing transmission spectra for incident light polarized perpendicular and parallel to the c-axis, in accordance with various embodiments;

FIG. 3B is a graph showing reflection spectra for incident light polarized perpendicular and parallel to the c-axis, in accordance with various embodiments;

FIG. 3C is a graph showing real (ε₁) and imaginary (ε₂) parts of the dielectric function for polarization perpendicular and parallel to the c-axis, extracted from a combination of ellipsometry and polarization-resolved transmission/reflectance measurements, in accordance with various embodiments;

FIG. 3D is a graph showing birefringence (Δn=n_{∥}−n_{⊥}), linear dichroism (Δk=k_{∥}−k_{⊥}) and normalized dichroism (n=(k_{∥}−k_{⊥})/(k_{∥}+k_{⊥})) for wavelengths from 210 nm to 16 μm, in accordance with various embodiments;

FIG. 3E is a graph showing a comparison of absolute birefringence values for various birefringent materials and BaTiSi₃ in the infrared, in accordance with various embodiments; and

FIG. 4 describes various method steps for forming a quasi-one-dimensional anisotropic crystal, in accordance with various embodiments.

### DETAILED DESCRIPTION

The following detailed description of various embodiments herein makes reference to the accompanying drawings, which show various embodiments by way of illustration. While these various embodiments are described in sufficient detail to enable those skilled in the art to practice the disclosure, it should be understood that other embodiments may be realized and that changes may be made without departing from the scope of the disclosure. Thus, the detailed description herein is presented for purposes of illustration only and not of limitation. Furthermore, any reference to singular includes plural embodiments, and any reference to more than one component or step may include a singular embodiment or step. Also, any reference to attached, fixed, connected, or the like may include permanent, removable, temporary, partial, full or any other possible attachment option. Additionally, any reference to without contact (or similar phrases) may also include reduced contact or minimal contact. It should also be understood that unless specifically stated otherwise, references to “a,” “an” or “the” may include one or more than one and that reference to an item in the singular may also include the item in the plural. Further, all ranges may include upper and lower values and all ranges and ratio limits disclosed herein may be combined.

The nature of light propagation in an anisotropic system can be described by complex refractive indices (n+ik) along the principal axes of the system. The optical anisotropy in a material can be quantified by the differences between the real parts of these indices as birefringence (Δn), and the imaginary parts of the indices as dichroism (Δk). Birefringence and dichroism are regularly found in inorganic crystals, liquid crystals and engineered form-birefringent structures such as, for example, plasmonic arrays and multi-slotted nanophotonic structures. Currently, inorganic solids widely used for high-performance polarizing optics have a maximum birefringence of approximately 0.3. Liquid crystals typically exhibit birefringence below 0.417, though careful designs such as connecting multiple aromatic rings have achieved birefringence of up to approximately 0.7. These bulky molecules are, however, difficult to synthesize and use. Anisotropic metamaterial or metasurface architectures with form-birefringence can offer large optical anisotropy, but their use remains limited due to optical losses and fabrication challenges.

Layered materials, such as, for example, graphite and some transition metal dichalcogenides, are highly anisotropic due to differences between their inter-layer and intra-layer bonding. However, the optic axis of these layered materials is typically the c-axis, and it is difficult to access the a-c plane with large anisotropy. Recently, black phosphorus with lower-symmetry individual layers and easily accessible in-plane anisotropy has attracted significant attention due to its anisotropy in vibrational, optical, and electrical properties. Nevertheless, the birefringence and dichroism in the a-b plane of black phosphorus remain modest, and its two-dimensional nature limits its utility in conventional optical systems.

Among various crystal structures, one can achieve large and accessible in-plane anisotropy in quasi-one-dimensional (quasi-1D) materials, where atoms are arranged in parallel chain-like structures. These rigid chains running along a high-symmetry principal axis ensure the optic axis is in a cleavage plane, which naturally reveals the large in-plane anisotropy between the intra-chain and inter-chain directions. The Clausius-Mossotti relation, which describes the relationship between the complex refractive index of a homogeneous medium and the polarizability of its constituent atoms, ions, or molecules, provides a clue to achieving large optical anisotropy in such structurally anisotropic materials. Intuitively, one can achieve large optical anisotropy in quasi-1D materials by tuning the anisotropy of the polarizability tensor, which requires controlling the nature and distribution of the constituent elements. We looked to engineer the polarizability tensor of quasi-1D materials that crystallize in a hexagonal BaNiO₃-type structure.

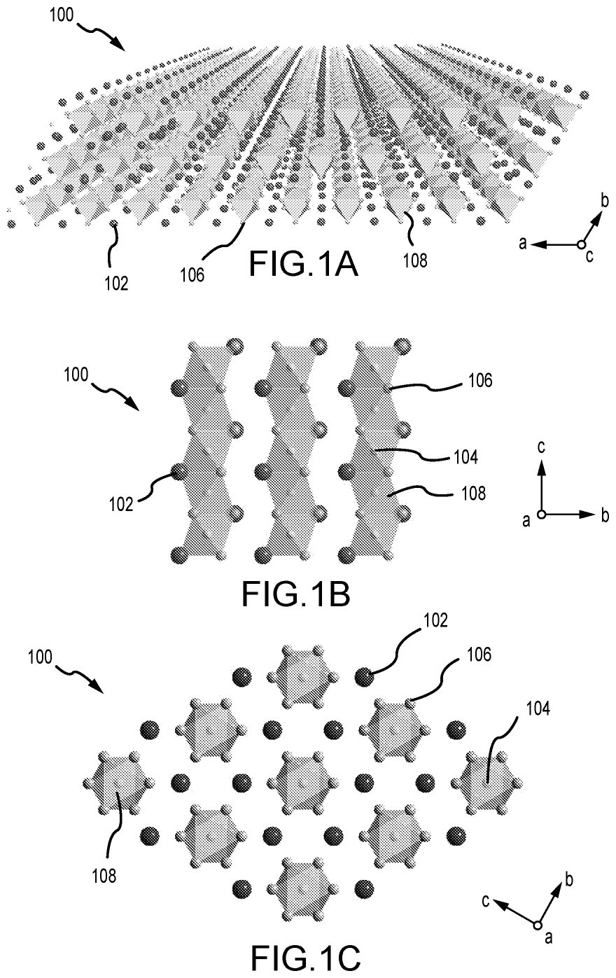

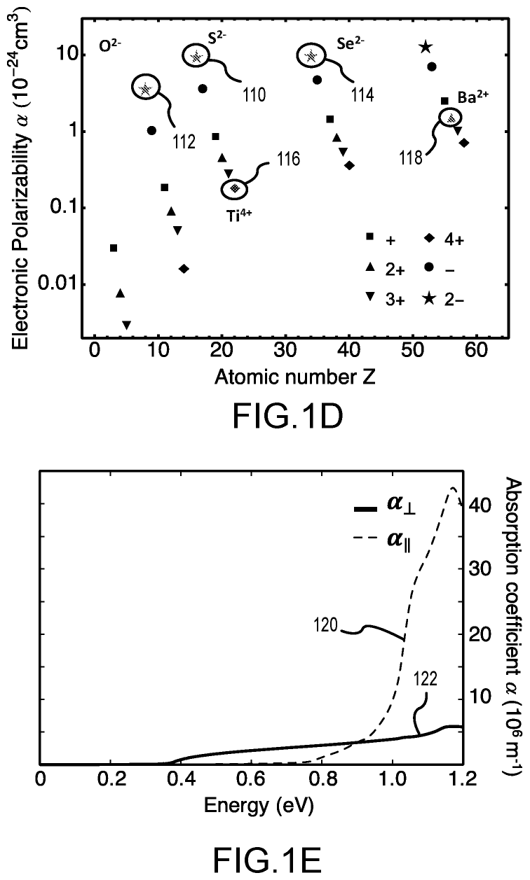

Referring to FIGS. 1A, 1B and 1C, for example, perspective, a-axis and c-axis views of a BaTiS₃ crystal plate (100) are illustrated, having Ba atoms (102), Ti atoms (104), S atoms (106) and TiSi₆ octahedra (108). These materials possess a general chemical formula, ABX₃, where A is typically an alkaline earth or alkali metal ion and B is a transition-metal ion surrounded by six anions (X). BX₆ octahedra sharing common faces are connected to form parallel chains along the c-axis, which is the six-fold rotation axis and the optic axis of the material. The electronic polarizability of some of the candidate ions for this structure are shown in FIG. 1D. Notably, the polarizability of S₂-(10.2 Å₃) (110) is much higher than O₂-(3.88 Å₃) (112), and is comparable with Se₂-(10.5 Å₃) (114). Ti₄₊ (116) with the lowest electronic polarizability among tetravalent transition-metal ions, and Ba₂₊ (118) with the highest value among common bivalent metal cations are a good combination to offer large polarizability difference between the c-axis and a/b-axis. Thus, we chose BaTiSi₃ as a model system among this class of quasi-1D materials to demonstrate large optical anisotropy.

BaTiS₃ is uniaxial with a diagonal dielectric tensor, εₐₐ=ε_{bb}≠ε_{cc}. We denote the two different components of the tensor with electric field perpendicular (ε_{⊥}=εₐₐ) and parallel (ε_{∥}=ε_{cc}) to the c-axis. We performed density functional calculations to verify the proposed heuristic selection process. The calculations yielded pronounced anisotropic optical properties and a large, broadband linear dichroism window. Calculated absorption coefficients for light polarized parallel (α_{∥}) (120) and perpendicular (α_{⊥}) (122) to the c-axis are shown in FIG. 1E. α_{∥} shows a prominent absorption edge, while α_{⊥} extends to lower energies. The calculated values of the absorption edges are sensitive to the approximations used for including correlation effects of Ti d orbitals. Irrespective of the parameters used, however, two distinct absorption edges in α_{∥} and α_{™} are observed. The origin of the anisotropic absorption edges can be understood by analyzing the band structure with dipole transition selections rules, and has been discussed for similar hexagonal structures. Note that the true fundamental band gap can be lower than the optical absorption edges seen here.

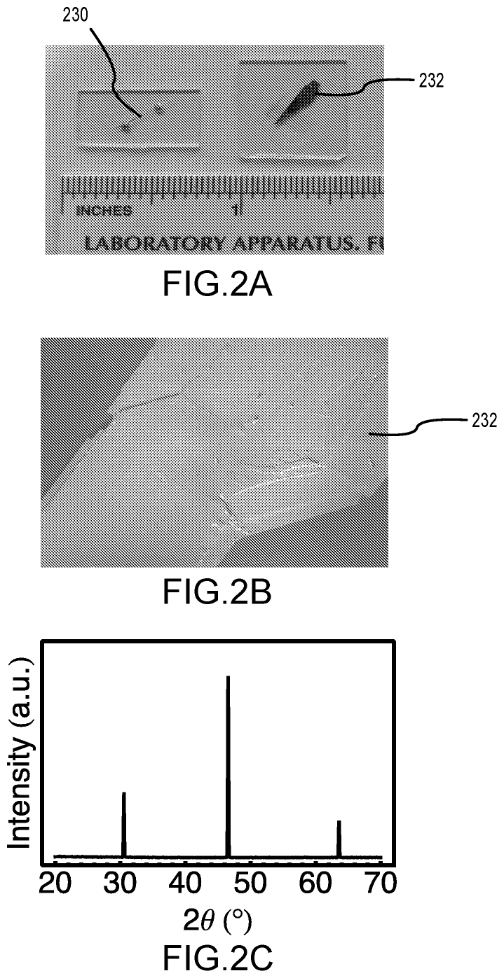

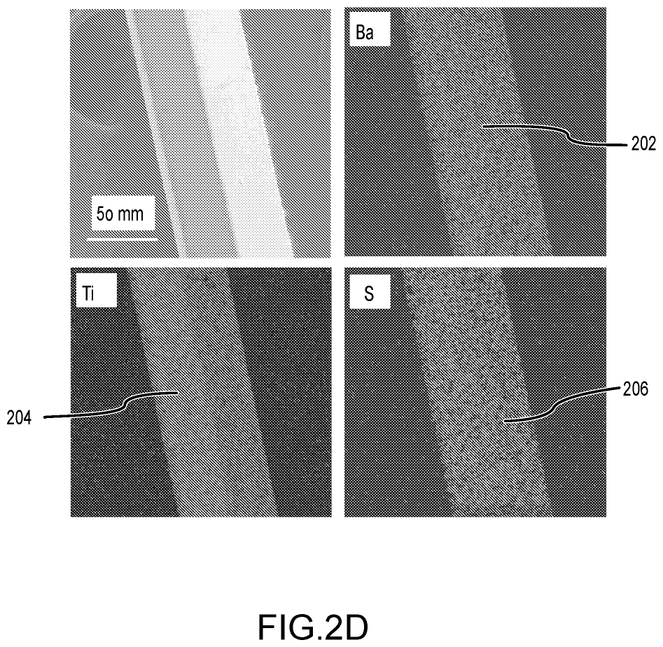

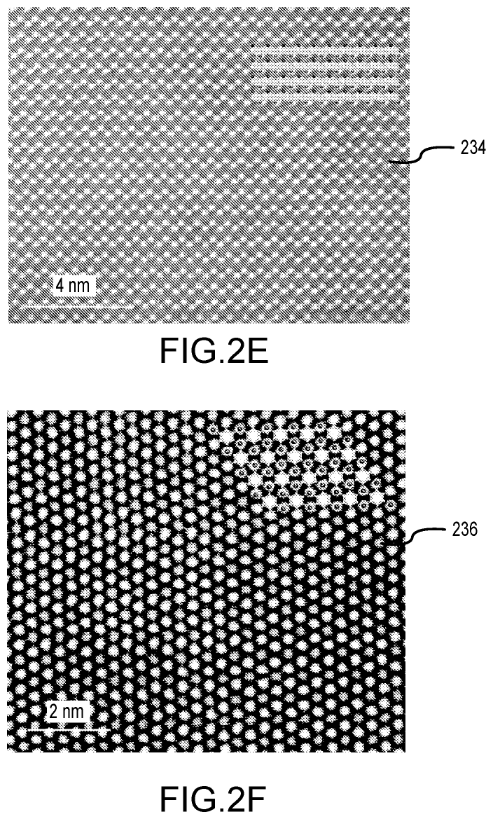

Referring now to FIGS. 2A-2G, large single-crystal platelets of BaTiS₃ with lateral dimensions of several millimeters were grown by a vapor transport method with iodine as a transport agent. As illustrated in FIG. 2A, we encountered two predominant morphologies: needle-like crystals (230) and platelet-like crystals (232). As illustrated in FIGS. 2B and 2D, scanning electron microscopy (SEM) images of these crystals show smooth crystal faces. A thin-film out-of-plane XRD scan of the crystal plate is shown in FIG. 2C. The presence of sharp {100}-type reflections proves the crystal face has {100} orientation with the c-axis in-plane. We identified the c-axis by confirming its six-fold rotational symmetry. Energy-dispersive X-ray spectroscopy (EDS) mapping showed the expected composition, as well as uniform distribution of all elements, including Ba atoms (202), Ti atoms (204) and S atoms (206). High-angle annular dark-field (HAADF) scanning transmission electron microscopy (STEM) images of the crystals along the a-axis (234) (illustrated in FIG. 2E) and the c-axis (236) (illustrated in FIG. 2F) clearly reveal the presence of parallel 1D chains along the c-axis and the hexagonal arrangement of the chains. Corresponding schematic crystal structures overlay the STEM images in FIGS. 2E and 2F.

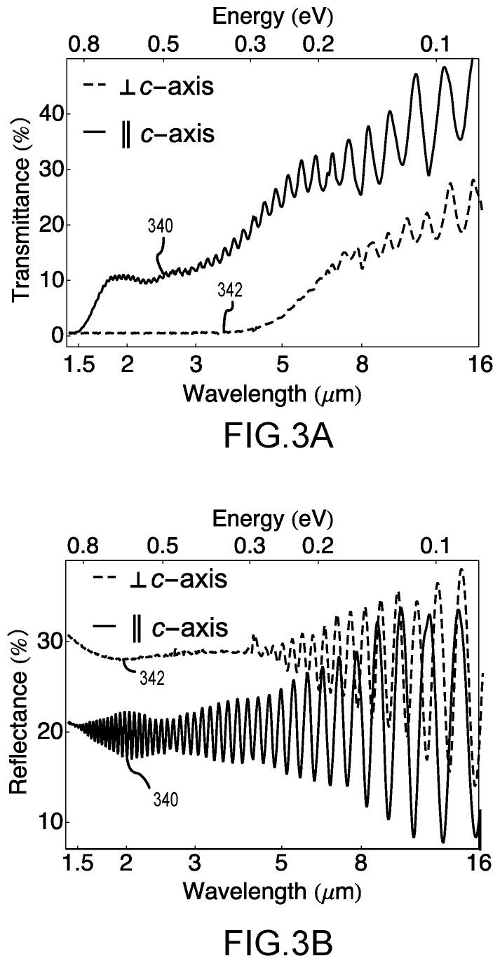

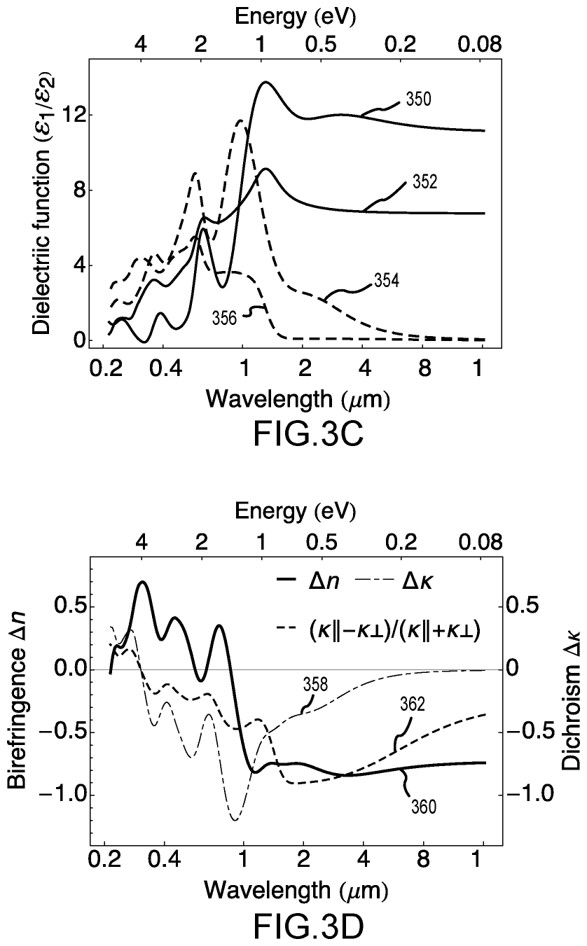

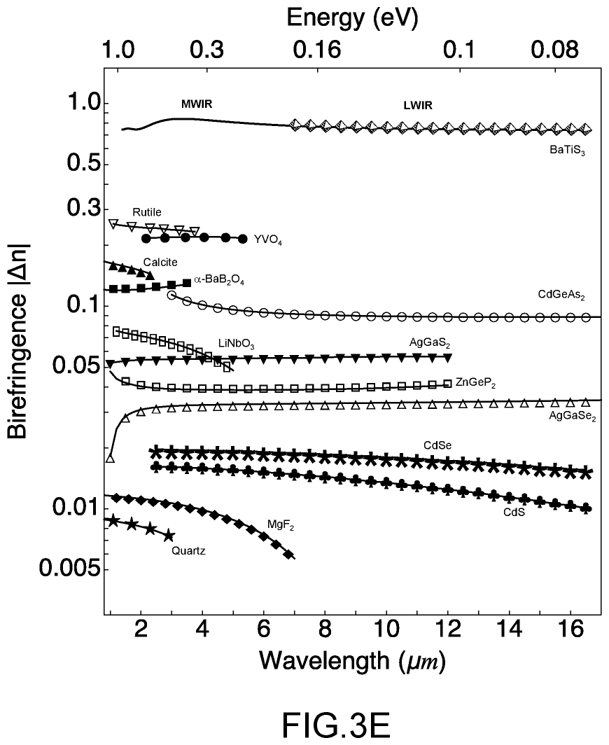

Referring now to FIGS. 3A-3B, polarization-resolved infrared spectroscopy was performed on a crystal plate of BaTiSi₃ to obtain the transmission and reflection spectra of the incident light polarized parallel (340) and perpendicular (342) to the c-axis. The thickness of the plate was estimated to be 13 μm by fitting to the Fabry-Perot fringes in the spectra. When the polarization is perpendicular (342) to the c-axis, the absorption edge was observed at 4.5 μm (0.27 eV). However, when the polarization is parallel (340) to the c-axis, the absorption edge was blue shifted to 1.6 μm (0.76 eV). The reflection spectra are consistent with the transmission spectra as the fringes vanish at wavelengths corresponding to the two different absorption edges. To fully quantify the degree of optical anisotropy, we performed generalized ellipsometry measurements over the spectral range of 210 to 1500 nm for several sample orientations. By combining these measurements with the polarization-resolved transmission and reflection measurements in shown in FIGS. 3A and 3B, we extracted the optical properties of BaTiS₃ over the 210 nm to 16 μm wavelength range.

Referring to FIG. 3C, the real (ε₁) and imaginary (ε₂) parts of the diagonalized dielectric tensor over the entire measured range are plotted as a function of wavelength. Specifically, ε_{1⊥} (350) and ε_{1∥} (352) and ε_{2⊥} (354) and ε_{2∥} (356) are plotted as functions of wavelength. Referring to FIG. 3D, the extracted wavelength-dependent birefringence (Δn=n_{∥}−n_{⊥}) (358), linear dichroism (Δk=k_{∥}−k_{⊥}) (360), and normalized dichroism (n=(k_{∥}−k_{⊥})/(k_{∥}+k_{⊥}) (362) are shown. The normalized dichroism is near unity in the strong dichroic window of 1.5-4.5 μm, and significant dichroism persists up to the visible range and changes sign at 300 nm. The transparent region for BaTiSi₃ starts at approximately 8 μm and persists to the longest measured wavelength, 16.7 μm. In this low-loss region, the material displays an unprecedented birefringence magnitude of up to 0.76, which is higher than the current largest birefringence in liquid crystals and more than twice as large as 0.29 in rutile. This appears the highest reported birefringence among anisotropic crystals, and is an order of magnitude larger than widely used long-wave infrared (LWIR) birefringent materials. BaTiS₃ possesses broadband, giant birefringence over the entire infrared spectrum, covering the short-wave infrared (SWIR), mid-wave infrared (MWIR), and LWIR atmospheric transmission windows.

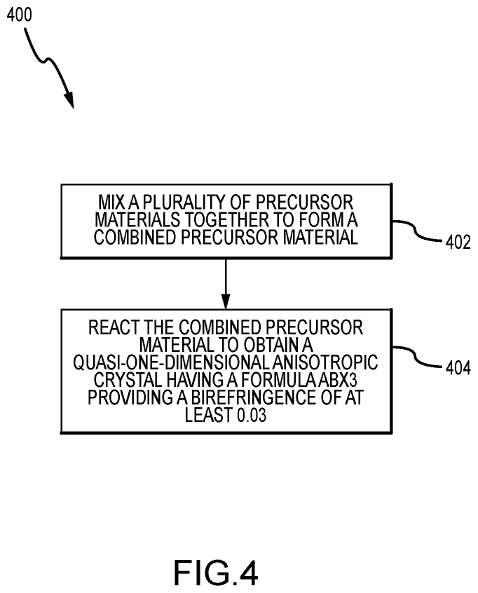

Referring now to FIG. 4, a method 400 for forming a crystalline material having an anisotropic, quasi-one-dimensional crystal structure is described. In various embodiments, a first step 402 includes mixing a plurality of precursor materials together to form a combined precursor material, the plurality of precursor materials including a transition-metal ion and at least one of an alkaline earth ion or an alkali metal ion. A second step 404 includes reacting the combined precursor material to obtain the crystalline material, the crystalline material having a formula ABX₃. In various embodiments, A is the at least one of the alkaline earth ion or the alkali metal ion and B is the transition-metal ion surrounded by six anions (X). In various embodiments, the quasi-one-dimensional anisotropic crystal provides a birefringence of at least 0.03, defined as the absolute difference in refractive-index values along different crystal axes, in at least a portion of one or both of the visible-wave spectrum or the infrared-wave spectrum.

In various embodiments, the at least one of the alkaline earth ion or the alkali metal ion includes at least one of barium, strontium or calcium; and the transition-metal ion includes at least one of titanium, vanadium, or a main group element including at least one of aluminum, silicon, germanium or gallium. In various embodiments, reacting the combined precursor material includes heating the combined precursor material to a predetermined temperature for a predetermined amount of time. In various embodiments, the predetermined temperature is at least 1472 degrees Fahrenheit (800 degrees C.) and the predetermined amount of time is at least 40 hours. In various embodiments, reacting the combined precursor material further includes heating the combined precursor material in an airtight vessel.

In conclusion, a material, such as, for example, barium titanium sulphide (BaTiS₃), which features an unprecedented degree of optical anisotropy, has been designed and realized. This anisotropy is achieved in an easily accessible crystal plane, and is enabled by the quasi-1D hexagonal perovskite structure of BaTiS₃, coupled with a judicious selection of the constituent ions (“chemical polarizability engineering”). Large single crystal plates of BaTiSi₃ were synthesized and fully characterized the complex-refractive-index tensor from the UV to the long-wave infrared. BaTiSi₃ crystals possess a broadband dichroism window and giant birefringence of up to 0.76, more than double the value in any other transparent homogeneous solid (to the best of our knowledge). We anticipate BaTiSi₃ and other quasi-1D materials will be broadly useful for next-generation imaging, communications, and sensing applications, especially for miniaturized photonic devices. We also expect these materials to possess large anisotropies in electrical, thermal and other physical properties, further expanding their scientific and technological importance.

### EXAMPLE

Starting materials, barium sulphide powder (Sigma-Aldrich, 99.9%), titanium powder (Alfa Aesar, 99.9%), sulphur pieces (Alfa Aesar, 99.999%), and iodine pieces (Alfa Aesar 99.99%), are stored and handled in an argon-filled glove box. Stoichiometric quantities of precursor powders with a total weight of 0.5 g were mixed and loaded into a ¾″ diameter quartz tube with 1.5 mm thickness along with around 0.5 mg/cm³ iodine inside the glove box. The tube was capped with ultra-torr fittings and a bonnet needle valve to avoid exposure to air. The tube was then evacuated and sealed using a blowtorch, with oxygen and natural gas as the combustion mixture. The sealed tube was about 12 cm in length, and was heated to 1000° C. with a 0.3° C./min ramp rate and held at 1000° C. for 60 hours. The samples were quenched to room temperature after the dwell time using a sliding furnace setup with a cooling rate of approximately 100° C./min.

Benefits, other advantages, and solutions to problems have been described herein with regard to specific embodiments. Furthermore, the connecting lines shown in the various figures contained herein are intended to represent exemplary functional relationships and/or physical couplings between the various elements. It should be noted that many alternative or additional functional relationships or physical connections may be present in a practical system. However, the benefits, advantages, solutions to problems, and any elements that may cause any benefit, advantage, or solution to occur or become more pronounced are not to be construed as critical, required, or essential features or elements of the disclosure. The scope of the disclosure is accordingly to be limited by nothing other than the appended claims, in which reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C. Different cross-hatching is used throughout the figures to denote different parts but not necessarily to denote the same or different materials.

Systems, methods and apparatus are provided herein. In the detailed description herein, references to “one embodiment”, “an embodiment”, “various embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments.

Furthermore, no element, component, or method step in the present disclosure is intended to be dedicated to the public regardless of whether the element, component, or method step is explicitly recited in the claims. No claim element herein is to be construed under the provisions of 35 U.S.C. 112(f) unless the element is expressly recited using the phrase “means for.” As used herein, the terms “comprises”, “comprising”, or any other variation thereof, are intended to cover a non-exclusive inclusion, such that a process, method, article, or apparatus that comprises a list of elements does not include only those elements but may include other elements not expressly listed or inherent to such process, method, article, or apparatus.

Finally, it should be understood that any of the above described concepts can be used alone or in combination with any or all of the other above described concepts. Although various embodiments have been disclosed and described, one of ordinary skill in this art would recognize that certain modifications would come within the scope of this disclosure. Accordingly, the description is not intended to be exhaustive or to limit the principles described or illustrated herein to any precise form. Many modifications and variations are possible in light of the above teaching.

1. A method for forming a crystalline material having an anisotropic, quasi-one-dimensional crystal structure, comprising:
mixing a plurality of precursor materials together to form a combined precursor material, the plurality of precursor materials including a transition-metal ion or a main group ion and at least one of an alkaline earth ion or an alkali metal ion; and
reacting the combined precursor material to obtain the crystalline material, the crystalline material having a formula ABX₃, wherein A is the at least one of the alkaline earth ion or the alkali metal ion and B is the transition-metal ion surrounded by six anions (X), and wherein the quasi-one-dimensional anisotropic crystal provides birefringence of at least 0.03, defined as the absolute difference in the real part of the complex refractive-index values along different crystal axes, in at least a portion of one or both of the visible-wave spectrum or the infrared-wave spectrum.

2. The method of claim 1, wherein:
the at least one of the alkaline earth ion or the alkali metal ion includes at least one of barium, strontium or calcium; and
the transition-metal ion includes at least one of titanium, vanadium, or a main group element including at least one of aluminum, silicon, germanium or gallium.

3. The method of claim 2, wherein reacting the combined precursor material includes heating the combined precursor material to a predetermined temperature for a predetermined amount of time.

4. The method of claim 3, wherein the predetermined temperature is at least 1472 degrees Fahrenheit (800 degrees C.) and the predetermined amount of time is at least 40 hours.

5. The method of claim 2, wherein reacting the combined precursor material further includes heating the combined precursor material in an airtight vessel.

6. The method of claim 2, wherein the plurality of precursor materials further includes at least one of sulphur, selenium, iodine, chlorine, bromine or a related precursor material.

7. The method of claim 6, wherein the crystalline material includes at least one of BaTiS₃, SrTiS₃, CsTaS₃, CsVS₃, CsNbS₃, RbTaS₃, RbVS₃, RbNbS₃, CsTaSe₃, CsVSe₃, CsNbSe₃, RbTaSe₃, RbVSe₃ or RbNbSe₃.

8. The method of claim 6, wherein the crystalline material includes at least one of BaTiS₃, SrTiS₃, CaTiS₃, BaVS₃, SrVS₃, CaVS₃, LaGaS₃, BaGeS₃, SrGeS₃, CaGeS₃, CaSiS₃, SrSiS₃, BaSiS₃, CeGaS₃ or EuGaS₃.

9. (canceled)

10. The method of claim 6, wherein the crystalline material includes at least one of KNiCl₃, RbMgCl₃, RbCoCl₃, RbNiCl₃, RbCuCl₃, RbZnCl₃, RbMgBr₃, RbCoBr₃, RbNiBr₃, RbCuBr₃, RbZnBr₃, CsMgCl₃, CsCoCl₃, CsNiCl₃, CsCuCl₃, CsZnCl₃, CsMgBr₃, CsCoBr₃, CsNiBr₃, CsCuBr₃, CsZnBr₃, CsMgI₃, CsCoI₃, CsNiI₃, CsCuI₃ or CsZnI₃.

11. (canceled)

12. The method of claim 1, wherein the crystalline material includes atoms arranged in a parallel chain-like structure.

13. The method of claim 1, wherein the crystalline material provides the birefringence greater than 0.15 in at least a portion of one or both of the visible-wave spectrum or the infrared-wave spectrum.

14. (canceled)

15. A method for forming a crystal exhibiting a birefringence, comprising:
mixing a plurality of precursor materials together to form a combined precursor material, the plurality of precursor materials including a transition-metal ion or a main group ion and at least one of an alkaline earth ion or an alkali metal ion; and
reacting the combined precursor material to obtain the crystal, having a formula ABX₃, wherein A is the at least one of the alkaline earth ion or the alkali metal ion and B is the transition-metal ion or the main group ion surrounded by six anions (X), and wherein the crystal provides the birefringence of at least 0.03 in at least a portion of one or both of the visible-wave spectrum or the infrared-wave spectrum.

16. The method of claim 15, wherein the crystal provides an absolute linear dichroism of at least 0.2 at some wavelength within the visible-wave spectrum or the infrared-wave spectrum, defined as the difference in the imaginary part of the refractive index, k, for polarization along at least two crystallographic axes on a cleavage plane.

17. The method of claim 15, wherein the crystal provides a difference in a wavelength within the visible-wave spectrum or the infrared-wave spectrum at which the imaginary part of the refractive index, k, reaches a value of 0.05 for light polarized parallel and perpendicular to the crystal c-axis.

18. The method of claim 15, wherein:
the at least one of the alkaline earth ion or the alkali metal ion includes at least one of barium, strontium or calcium; and
the transition-metal ion includes at least one of titanium or vanadium, or the main group ion includes at least one of aluminum, silicon, germanium or gallium.

19. (canceled)

20. The method of claim 18, wherein the plurality of precursor materials further includes at least one of sulphur, selenium, iodine or chlorine.

21. The method of claim 20, wherein the crystal includes at least one of BaTiS₃, SrTiS₃, CaTiS₃, BaVS₃, SrVS₃, CaVS₃, LaGaS₃, BaGeS₃, SrGeS₃, CaGeS₃, CaSiS₃, SrSiS₃, BaSiS₃, CeGaS₃ or EuGaS₃.

22. (canceled)

23. The method of claim 20 wherein the crystal includes at least one of BaTiSe₃, SrTiSe₃, CaTiSe₃, BaVSe₃, SrVSe₃, CaVSe₃, LaGaSe₃, BaGeSe₃, SrGeSe₃, CaGeSe₃, CaSiSe₃, SrSiSe₃, BaSiSe₃, CeGaSe₃ or EuGaSe₃.

24. The method of claim 18 wherein the crystal includes atoms arranged in a parallel chain-like structure.

25. (canceled)

26. The method of claim 15 wherein the crystal provides the birefringence greater than 0.30 in at least a portion of one or both of the visible-wave spectrum or the infrared-wave spectrum.
